(19) United States
(12) Patent Application Publication
(10) Pub. No.: US 2006/0079029 A1
(43) Pub. Date: Apr. 13, 2006

(54) Flexible circuit board processing method

(76) Inventor: Akihiro Nakamura, Tokyo-To (JP)

Correspondence Address: JACOBSON HOLMAN PLLC, 400 SEVENTH STREET N.W., SUITE 600, WASHINGTON, DC, 20004, US

(21) Appl. No.: 11/248,207

(22) Filed: Oct. 13, 2005

(30) Foreign Application Priority Data
Oct. 13, 2004 (JP) 2004-298493

(51) Int. Cl. H01L 23/48; H01L 23/28; H01L 21/50; H01L 23/053

(52) U.S. Cl. 438/127; 438/126; 438/118; 257/787; 257/701; 257/688

(57) ABSTRACT

It is an object of this invention to provide a flexible circuit board processing method which controls an outflow of a sealing material to be appropriate when packaging a component on a flexible circuit board. There is provided a flexible circuit board processing method for, when packaging a chip component (10) on a flexible circuit board, filling the surroundings of the chip component in a component-mounting portion on the board with a sealing material (20), wherein a surface (A) of the component-mounting portion is subjected in advance to a modification process to improve the wettability to the sealing material.

### BACKGROUND OF THE INVENTION

1. Field of the Invention

The present invention relates to a flexible circuit board processing method and, more particularly, to a processing method for preventing an outflow of a sealing material with which the gap between a chip component and a circuit board is to be filled for the purpose of reinforcement after the chip component is packaged on the circuit board.

2. Related Art

Components have been being packaged on a circuit board more and more densely. In the case of a flip chip component, the flip chip component is connected to a board with solder, and the gap between the flip chip component and the board is filled with a sealing material, thereby reinforcing the connection. To satisfactorily perform this operation of filling a gap with a sealing material, there have been made various proposals (Japanese Patent Laid-Open No. 9-139566, Japanese Patent Laid-Open No. 2001-110825, and Japanese Patent Laid-Open No. 2003-124610).

To increase component packaging density, it is necessary to fill, with a sealing material, only a limited area including the gap between each component and a circuit board and its surroundings and not to let the sealing material spread excessively.

In electrical connection by soldering, when soldering a flip chip component to a board and then charging a sealing material, the sealing material having flowed out onto a cover film which covers the circuit pattern of the board may spread to a portion other than the flip chip to be filled, which causes inhibition of high-density packaging and in the meantime causes the component to be filled to suffer from an insufficiency of the filling quantity. Therefore, it is necessary to control an outflow of the sealing material.

### SUMMARY OF THE INVENTION

The present invention has been made in consideration of the above-described problem, and has as its object to provide a flexible circuit board processing method which controls an outflow of a sealing material to be appropriate when packaging a component on a flexible circuit board.

In order to achieve the above-described object, according to the present invention, there is provided

a flexible circuit board processing method for, when packaging a chip component on a flexible circuit board, filling surroundings of the chip component in a component-mounting portion on the board with a sealing material, wherein a surface of the component-mounting portion is subjected in advance to a modification process to improve wettability to the sealing material.

As described above, since the present invention performs modification processing for a component-mounting portion in a circuit board, the wettability of the component-mounting portion becomes far better than that of a portion other than the component-mounting portion. Although a sealing material spreads in the component-mounting portion, it can be prevented from spreading to the portion other than the component-mounting portion. As a result, the surroundings of a component are satisfactorily filled with a sealing material, and the sealing material is prevented from spreading to beyond the surroundings.

### BRIEF DESCRIPTION OF THE DRAWINGS

FIG. 1 is a view for explaining a device configuration for surface modification processing according to the present invention;

FIGS. 2(A) and 2(B) show in more detail an area A of the flexible circuit board shown in FIG. 1, in which FIG. 2(A) is a plan view, and FIG. 2(B), a sectional view;

FIG. 3 is a sectional view showing a state wherein a flip chip component 10 is mounted on the flexible circuit board, and a sealing material 20 is charged;

FIGS. 4(A) and 4(B) are sectional views, respectively, showing the filling condition of the sealing material 20 in the entire flip chip component 10 including the portion shown in FIG. 3 and the covering condition of a covercoat layer 30; and

FIGS. 5(A) and 5(B) are sectional views, respectively, showing a state wherein the chip component 10 is connected to the flexible circuit board by wire bonding and a state wherein the chip component 10 is covered with a globe-top material 40 serving as a sealing material after the connection, respectively.

### DETAILED DESCRIPTION OF THE INVENTION

Hereinafter, an embodiment of the present invention will be described with reference to the accompanying drawings.

### FIRST EMBODIMENT

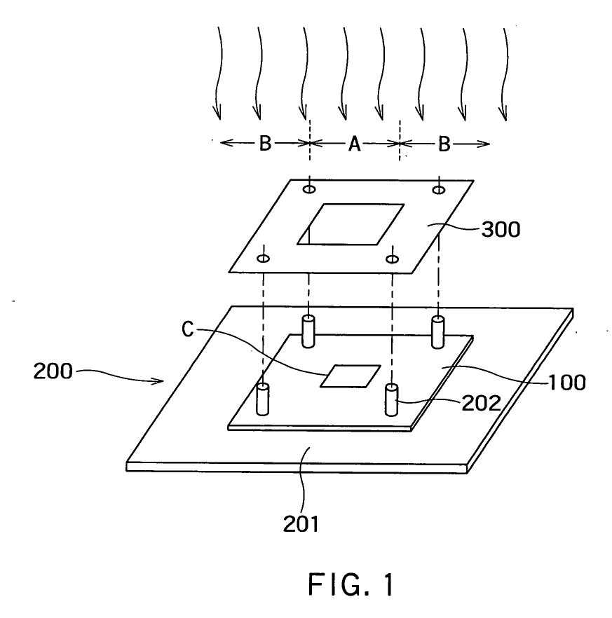

FIG. 1 shows a device configuration for performing modification processing for a circuit board according to the present invention. As shown in FIG. 1, a flexible circuit board 100 serving as a piece of work is set using alignment pins 202 provided upright on a base 201 of a jig 200. A cover having an opening C in its center is provided as the uppermost surface of the flexible circuit board 100.

The upper surface shown in FIG. 1 of the flexible circuit board 100 is covered with a mask 300. The mask 300 protects a non-irradiated area B when irradiating an area A including the opening C of the flexible circuit board 100 with ultraviolet rays (UV) or plasma and is formed like a metal or resin plate. The area A is an area within which a sealing material is permitted to flow.

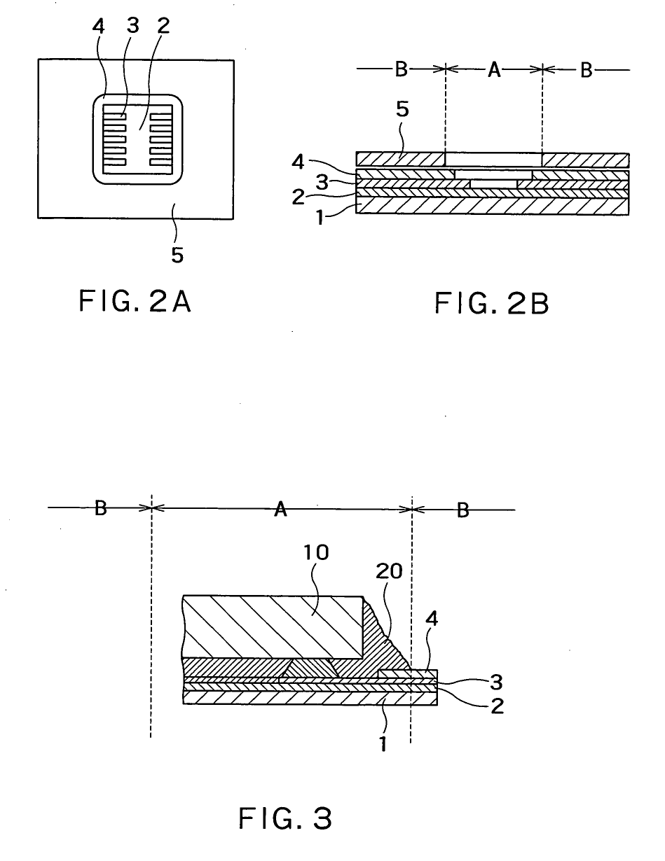

FIGS. 2(A) and 2(B) show in more detail the area A of the flexible circuit board shown in FIG. 1, in which FIG. 2(A) is a plan view, and FIG. 2(B), a sectional view. As shown in FIG. 2(B), the flexible circuit board is formed by sequentially stacking a reinforcing material 1, base material 2, wiring layer 3, and cover 4 (an adhesive layer is not shown). A mask 5 is laid over the flexible circuit board, thereby exposing only the area A.

When the flexible circuit board is irradiated with UV, plasma, or the like through the mask, only the area A is cleaned, and the surface is modified. After the modification processing, the wettability of the surface to a sealing material called an underfill material is improved, and the outflow characteristics become better.

FIG. 3 shows a state wherein a flip chip component 10 is mounted on the flexible circuit board, and a sealing material 20 is charged. The flip chip component 10 is connected and fixed to a bump of the flexible circuit board by soldering, and the gap between the flip chip component 10 and the flexible circuit board 100 is filled with the sealing material 20. With this arrangement, the flip chip component 10 is securely fixed to the base material 2, wiring layer 3, and cover 4 of the flexible circuit board 100.

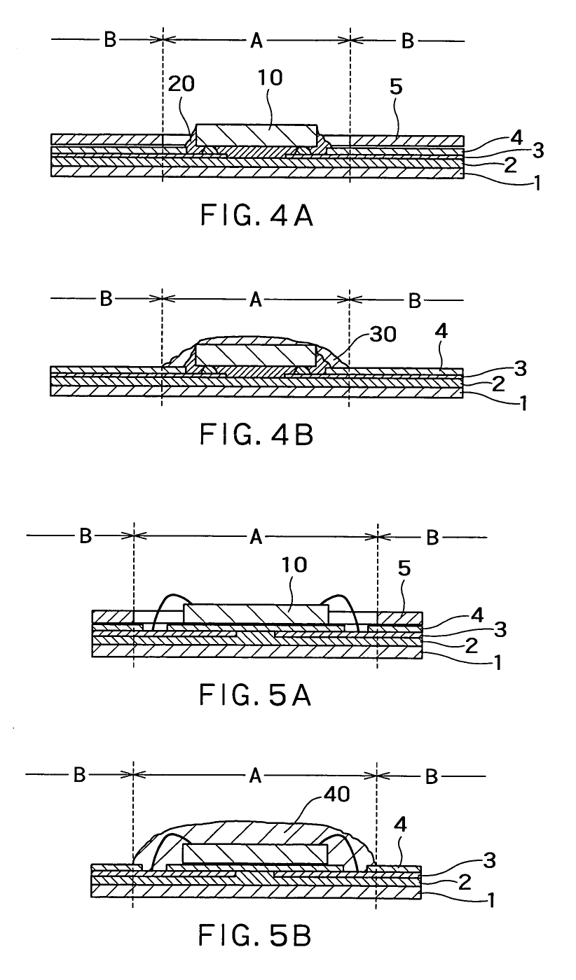

FIGS. 4(A) and 4(B) show the filling condition of the sealing material 20 in the entire flip chip component 10 including the portion shown in FIG. 3 and the covering condition of a covercoat layer 30, respectively.

In the case of FIG. 4(A), the sealing material 20 spreads within a range barely enough to reach the cover 4, but not over the area A. When in this state, surface modification processing is performed for the area A using the mask 5, and the area A is covered with the covercoat layer 30, the covercoat layer 30 spreads over the area A and does not spread to the area B.

As a result, individual components can be securely sealed while increasing the component packaging density.

FIGS. 5(A) and 5(B) show a state wherein the chip component 10 is connected to the flexible circuit board by wire bonding and a state wherein the chip component 10 is covered with a globe-top material 40 serving as a sealing material after the connection, respectively.

In this case as well, after the surface modification processing for the area A using the mask 5, the area A is covered with the globe-top material 40. As a result, the wettability of the surface in the area A including the chip component 10 to the globe-top material 40 is improved, and the area A is satisfactorily covered with the globe-top material 40. Additionally, the globe-top material 40 does not spread to the area B.

What is claimed is:

1. A flexible circuit board processing method for, when packaging a chip component on a flexible circuit board, filling surroundings of the chip component in a component-mounting portion on the board with a sealing material,
wherein a surface of the component-mounting portion is subjected in advance to a modification process to improve wettability to the sealing material.

2. The flexible circuit board processing method according to claim 1, wherein
the component-mounting portion includes an end of a cover provided to cover a circuit portion in the flexible circuit board.

3. The flexible circuit board processing method according to claim 1, wherein
the modification process is UV cleaning.

4. The flexible circuit board processing method according to claim 1, wherein
the modification process is plasma cleaning.
